(19) United States
(12) Patent Application Publication
(10) Pub. No.: US 2025/0022973 A1
(43) Pub. Date: Jan. 16, 2025

(54) EPITAXIAL STRUCTURE OF NONPOLAR AlGaN-BASED DEEP-ULTRAVIOLET (DUV) PHOTOELECTRIC DETECTOR AND PREPARATION METHOD THEREOF

(71) Applicant: SOUTH CHINA UNIVERSITY OF TECHNOLOGY, Guangzhou (CN)

(72) Inventors: Wenliang WANG, Guangzhou (CN); Jianhua DUAN, Guangzhou (CN); Guoqiang LI, Guangzhou (CN)

(73) Assignee: SOUTH CHINA UNIVERSITY OF TECHNOLOGY, Guangzhou (CN)

(21) Appl. No.: 18/276,667

(22) PCT Filed: Sep. 27, 2022
(86) PCT No.: PCT/CN2022/121833

§ 371 Date: Aug. 10, 2023

(30) Foreign Application Priority Data
Apr. 8, 2022 (CN) 202210363310.4

(51) Int. Cl. H01L 31/0304; H01L 31/0392; H01L 31/09; H01L 31/18

(52) U.S. Cl. CPC H01L 31/03048; H01L 31/0392; H01L 31/09; H01L 31/1848; H01L 31/1852; H01L 31/1864

(57) ABSTRACT

An epitaxial structure of a nonpolar AlGaN-based deep-ultraviolet (DUV) photoelectric detector and a preparation method thereof are provided. The epitaxial structure of the nonpolar AlGaN-based DUV photoelectric detector includes a nonpolar AlN buffer layer, a nonpolar Al_{0.15}Ga_{0.85}N buffer layer, and a nonpolar Al_{0.7}Ga_{0.3}N epitaxial layer that are sequentially grown on a LaAlO₃ substrate. The LaAlO₃ substrate takes a (100) plane as an epitaxial plane, and AlN[11-20] as an epitaxial growth direction. With the LaAlO₃ substrate, the epitaxial structure reduces dislocations and stresses between the substrate and the epitaxial buffer layer. By designing two AlGaN epitaxial buffer layers with different components, the epitaxial structure reduces a dislocation density and a surface roughness of the nonpolar AlGaN epitaxial layer, further accelerates photoresponse and detectivity of the detector, and enhances overall performance of the nonpolar AlGaN-based DUV photoelectric detector.

### CROSS REFERENCE TO THE RELATED APPLICATIONS

This application is the national phase entry of International Application No. PCT/CN2022/121833, filed on Sep. 27, 2022, which is based upon and claims priority to Chinese Patent Application No. 202210363310.4, filed on Apr. 8, 2022, the entire contents of which are incorporated herein by reference.

### TECHNICAL FIELD

The present disclosure relates to the technical field of photoelectric detectors, and in particular, to an epitaxial structure of a nonpolar AlGaN-based deep-ultraviolet (DUV) photoelectric detector and a preparation method thereof.

### BACKGROUND

As a third-generation semiconductor material, the AlGaN material features a wide band gap, a strong radiation resistance, a high saturated electron drift velocity, and a high thermal stability, and has been widely applied to high-performance photoelectric devices. With an adjustable band gap capable of covering UV light from 200 nm to 365 nm, the AlGaN material is desirable to prepare a DUV photoelectric detector.

Compared with a conventional polar C-plane AlGaN material, the nonpolar plane AlGaN material is not susceptible to spontaneous polarization, does not cause a quantum-confined Stark effect, and is optically anisotropic. Therefore, the nonpolar plane AlGaN-based device has a higher stability and a better application potential than a polar plane AlGaN-based device. Due to serious lattice mismatch with a substrate, the existing heteroepitaxially grown nonpolar plane AlGaN material has a poor crystalline quality, a rough surface, a high dislocation density, etc, which seriously restricts the performance of the nonpolar plane AlGaN-based device. Hence, to achieve better performance of the detector, it is of great significance to research a high-quality nonpolar AlGaN material.

### SUMMARY

The present disclosure provides an epitaxial structure of a nonpolar AlGaN-based DUV photoelectric detector and a preparation method thereof, to solve shortages of the prior art. With the LaAlO₃ substrate, the present disclosure reduces dislocations and stresses between the substrate and the epitaxial buffer layer, and improves photoresponse of the DUV photoelectric detector. By designing two AlGaN epitaxial buffer layers with different components, the present disclosure relieves chemical incompatibility between the epitaxial layer and the substrate, reduces a dislocation density and a surface roughness of the nonpolar AlGaN epitaxial layer, and enhances performance of the nonpolar AlGaN-based DUV photoelectric detector. Since the LaAlO₃ material is unstable at a high temperature, the present disclosure uses pulsed laser deposition (PLD), and ablates a target material with laser. The present disclosure can grow an epitaxial material at a low temperature to suppress interfacial reaction between the LaAlO₃ substrate and the AlGaN material, and thus the prepared nonpolar AlGaN-based DUV photoelectric detector has fast response and high sensitivity.

A first objective of the present disclosure is to provide an epitaxial structure of a nonpolar AlGaN-based DUV photoelectric detector.

A second objective of the present disclosure is to provide a preparation method of an epitaxial structure of a nonpolar AlGaN-based DUV photoelectric detector.

The first objective of the present disclosure may be achieved through the following technical solutions:

An epitaxial structure of a nonpolar AlGaN-based DUV photoelectric detector includes a LaAlO₃ substrate, where a nonpolar AlN buffer layer, a nonpolar Al_{0.15}Ga_{0.85}N buffer layer, and a nonpolar Al_{0.7}Ga_{0.3}N epitaxial layer are sequentially grown on the LaAlO₃ substrate; and the LaAlO₃ substrate takes a (100) plane as an epitaxial plane, and AlN[11-20] as an epitaxial growth direction.

Further, the nonpolar AlN buffer layer has a thickness of 300 nm to 400 nm.

Further, the nonpolar Al_{0.15}Ga_{0.85}N buffer layer has a thickness of 350 nm to 400 nm.

Further, the nonpolar Al_{0.7}Ga_{0.3}N epitaxial layer has a thickness of 450 nm to 550 nm.

The second objective of the present disclosure may be achieved through the following technical solutions:

A preparation method of an epitaxial structure of a nonpolar AlGaN-based DUV photoelectric detector includes:
selecting a LaAlO₃ substrate, and cleaning a surface of the LaAlO₃ substrate;
putting the cleaned LaAlO₃ substrate into an ultrahigh vacuum (UHV) chamber, and annealing the cleaned LaAlO₃ substrate at a high temperature to remove surface contamination;
charging nitrogen to the UHV chamber, and epitaxially growing a nonpolar AlN buffer layer on the LaAlO₃ substrate by PLD;
changing a target material in an environment of growing the nonpolar AlN buffer layer, and growing a nonpolar Al_{0.15}Ga_{0.85}N buffer layer on the nonpolar AlN buffer layer in-situ; and
changing the target material in the environment of growing the nonpolar AlN buffer layer, and growing a nonpolar Al_{0.7}Ga_{0.3}N epitaxial layer on the nonpolar Al_{0.15}Ga_{0.85}N buffer layer.

The LaAlO₃ substrate takes a (100) plane as an epitaxial plane, and AlN[11-20] as an epitaxial growth direction.

Further, the environment of growing the nonpolar AlN buffer layer is specifically as follows:
by keeping a vacuum degree in the UHV chamber, a laser energy at 220 mJ to 300 mJ, a laser frequency at 15 Hz to 30 Hz, a nitrogen flow at 2 sccm to 8 sccm, and a nitrogen pressure in the vacuum chamber at 6 mTorr to 10 mTorr, the nonpolar AlN buffer layer is grown in an N-rich atmosphere.

Further, the nonpolar AlN buffer layer is epitaxially grown on the LaAlO₃ substrate, and an Al source is an AlN high-purity ceramic target material.

Further, the nonpolar Al_{0.15}Ga_{0.85}N buffer layer is grown on the nonpolar AlN buffer layer in-situ, and the target material is gallium-rich AlGaN ceramic.

Further, the nonpolar Al_{0.7}Ga_{0.3}N epitaxial layer is grown on the Al_{0.15}Ga_{0.85}N buffer layer, and the target material is aluminum-rich AlGaN ceramic.

Further, the nonpolar AlN buffer layer has a thickness of 300 nm to 400 nm;
the nonpolar Al_{0.15}Ga_{0.85}N buffer layer has a thickness of 350 nm to 400 nm; and the nonpolar Al_{0.7}Ga_{0.3}N epitaxial layer has a thickness of 450 nm to 550 nm.

Compared with the prior art, the present disclosure has the following beneficial effects:

1. The lattice mismatch between the (110)-plane LaAlO₃ substrate and the (11-20) plane of the nonpolar AlN material is small and is only 0.4% (theoretical value), so the epitaxial structure of a nonpolar AlGaN-based DUV photoelectric detector provided by the present disclosure is a perfect heteroepitaxial substrate material. It can effectively reduce dislocations and stresses between the substrate and the epitaxial buffer layer, improve a crystalline quality of the grown material, enhance a detectivity of the AlGaN-based DUV photoelectric detector, reduce a dark current of the detector, and accelerate photoresponse of the DUV photoelectric detector.

2. The present disclosure grows the epitaxial structure of the nonpolar AlGaN-based DUV photoelectric detector by low-temperature PLD, thereby effectively suppressing interfacial reaction between the substrate and the epitaxial layer at a high temperature, and ensuring growth of the high-quality nonpolar AlGaN-based epitaxial thin film. If the thin film is grown by conventional metal organic chemical vapor deposition (MOCVD) and the like at the high temperature, since the LaAlO₃ material is unstable at the high temperature, oxygen atoms separated out from the LaAlO₃ substrate react with the epitaxial material to form an interfacial reaction layer with a high density of dislocation defects, thus seriously affecting the crystalline quality. By designing two AlGaN epitaxial buffer layers with different components, the present disclosure relieves chemical incompatibility between the epitaxial layer and the substrate, and gradually releases tensile stresses. This further reduces a dislocation density and a surface roughness of the nonpolar AlGaN epitaxial layer, reduces the dark current of the detector, accelerates the photoresponse and detectivity, and enhances overall performance of the nonpolar AlGaN-based DUV photoelectric detector.

3. The present disclosure employs the nonpolar AlGaN material as a basic material of the device. Compared with a polar AlGaN material, the nonpolar AlGaN material is not susceptible to spontaneous polarization and a built-in electric field, thereby effectively improving the photoresponse of the DUV photoelectric detector. Meanwhile, the nonpolar AlGaN material is optically anisotropic and polarization-sensitive, such that the DUV photoelectric detector is able to detect polarized light.

### BRIEF DESCRIPTION OF THE DRAWINGS

To describe the technical solutions in the embodiments of the present disclosure or in the prior art more clearly, the following briefly describes the drawings required for describing the embodiments or the prior art. Apparently, the drawings in the following description show some embodiments of the present disclosure, and those of ordinary skill in the art may still derive other drawings from these drawings without creative efforts.

FIG. 1 illustrates a schematic structural view of an epitaxial structure of a nonpolar AlGaN-based DUV photoelectric detector according to an embodiment of the present disclosure;

FIG. 2 illustrates a reflection high-energy electron diffraction (RHEED) pattern of a nonpolar AlGaN epitaxial wafer in a direction according to Embodiment 1 of the present disclosure; and

FIG. 3 illustrates a test graph of an X-ray rocking curve of a nonpolar AlGaN(11-20) thin film according to Embodiment 1 of the present disclosure.

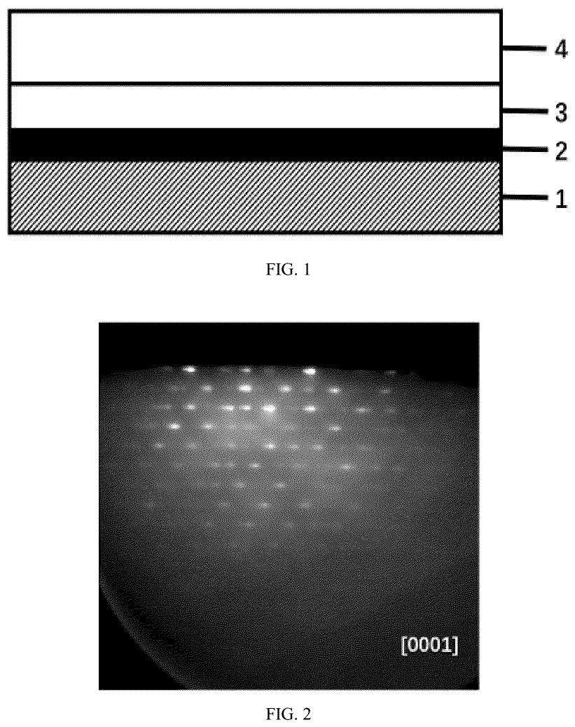

In FIG. 1:
1—LaAlO₃ substrate, 2—nonpolar AlN buffer layer, 3—nonpolar Al_{0.15}Ga_{0.85}N buffer layer, and 4—nonpolar Al_{0.7}Ga_{0.3}N epitaxial layer.

### DETAILED DESCRIPTION OF THE EMBODIMENTS

In order to make objectives, technical solutions and advantages in the embodiments of the present disclosure clearer, the technical solutions in the embodiments of the present disclosure are clearly and completely described below with reference to the accompanying drawings in the embodiments of the present disclosure. Apparently, the described embodiments are merely a part rather than all of the embodiments of the present disclosure. All other embodiments derived from the embodiments in the present disclosure by a person of ordinary skill in the art without creative efforts should fall within the protection scope of the present disclosure. It should be understood that the specific embodiments described herein are merely used to explain the present disclosure, rather than to limit the present disclosure.

An embodiment provides a preparation method of an epitaxial structure of a nonpolar AlGaN-based DUV photoelectric detector, including the following steps:

(1) Selection of a substrate and a crystal orientation: The LaAlO₃ substrate takes a (100) plane as an epitaxial plane, and an AlN[11-20] direction as an epitaxial growth direction of a material.

(2) Surface cleaning of the substrate: The LaAlO₃ substrate is sequentially put into acetone, anhydrous ethanol and deionized water for ultrasonic cleaning, taken out, washed with the deionized water, and blow-dried with hot high-purity nitrogen.

(3) Surface annealing of the substrate for impurity removal: The LaAlO₃ substrate is put into a UHV chamber. By pumping a vacuum degree in the chamber to 2.5*10-10 torr to 2.9*10-10 torr, and heating the chamber to 600° C. to 800° C., the substrate is annealed to remove surface contamination and obtain a flat surface.

(4) Growth of a nonpolar AlN buffer layer: After the substrate is annealed, by cooling the chamber to 450° C., and keeping the vacuum degree in the chamber, a laser energy at 220 mJ to 300 mJ, a laser frequency at 15 Hz to 30 Hz, a nitrogen flow at 2 sccm to 8 sccm, and a nitrogen pressure in the vacuum chamber at 6 mTorr to 10 mTorr, the nonpolar AlN buffer layer is grown by PLD in an N-rich atmosphere. An Al source is an AlN high-purity ceramic target material.

(5) Epitaxial growth of a nonpolar Al_{0.15}Ga_{0.85}N buffer layer: Upon the growth of the nonpolar AlN buffer layer, by keeping the vacuum degree in the chamber, the laser energy, the laser frequency and the nitrogen flow unchanged, and changing a target material into gallium-rich AlGaN ceramic, the nonpolar Al_{0.15}Ga_{0.85}N buffer layer is grown on the nonpolar AlN buffer layer in-situ.

(6) Growth of a nonpolar Al_{0.7}Ga_{0.3}N epitaxial layer: Upon the growth of the nonpolar Al_{0.15}Ga_{0.85}N buffer layer, by keeping the vacuum degree in the chamber, the laser energy, the laser frequency and the nitrogen flow unchanged, and changing the target material into aluminum-rich AlGaN ceramic, the nonpolar Al_{0.7}Ga_{0.3}N epitaxial layer is epitaxially grown on the nonpolar Al_{0.15}Ga_{0.85}N buffer layer.

As shown in FIG. 1, the epitaxial structure of a nonpolar AlGaN-based DUV photoelectric detector prepared in the embodiment includes the nonpolar AlN buffer layer 2, the nonpolar Al_{0.15}Ga_{0.85}N buffer layer 3, and the nonpolar Al_{0.7}Ga_{0.3}N epitaxial layer 4 that are sequentially grown on the LaAlO₃ substrate 1. The nonpolar AlN layer has a thickness of 300 nm to 400 nm. The nonpolar Al_{0.15}Ga_{0.85}N buffer layer has a thickness of 350 nm to 400 nm. The nonpolar Al_{0.7}Ga_{0.3}N epitaxial layer has a thickness of 450 nm to 550 nm.

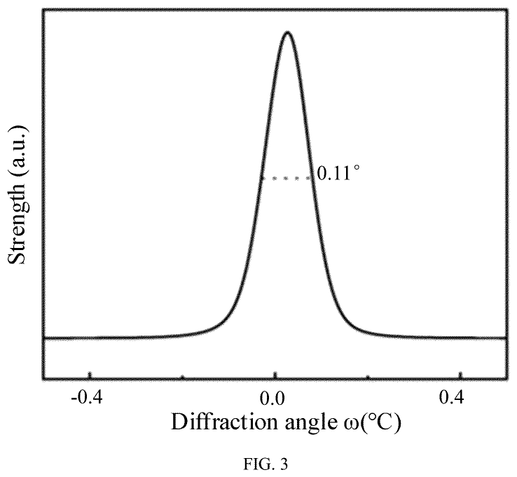

The RHEED diffraction pattern for a surface of the nonpolar AlGaN thin film of the grown epitaxial structure in the direction is as shown in FIG. 2. The diffraction pattern shows subtle stripes, which indicates that there are single crystals with a good quality on the surface. The test result of the X-ray rocking curve of the nonpolar AlGaN (11-20) thin film is as shown in FIG. 3. The half-peak width is 0.11°, which indicates that the thin film has a good crystalline quality.

### Embodiment 1

The embodiment provides a preparation method of an epitaxial structure of a nonpolar AlGaN-based DUV photoelectric detector, including the following steps:

(1) Selection of a substrate and a crystal orientation: The LaAlO₃ substrate takes a (100) close-packed plane as an epitaxial plane, and an AlN[11-20] direction as an epitaxial growth direction of a material.

(2) Surface cleaning of the substrate: The LaAlO₃ substrate is sequentially put into acetone, anhydrous ethanol and deionized water to ultrasonically clean for 5 min, taken out, washed with the deionized water, and blow-dried with hot high-purity nitrogen.

(3) Surface annealing of the substrate for impurity removal and leveling: The cleaned LaAlO₃ substrate is put into a UHV chamber. By pumping a vacuum degree in the chamber to 2.5*10-10 torr, and heating the chamber to 600° C., the substrate is annealed for 30 min.

(4) Growth of a nonpolar AlN buffer layer: by cooling the chamber to 450° C., keeping a vacuum degree in the chamber at 2.5*10-10 torr, a laser energy at 220 mJ and a laser frequency at 15 Hz, charging a nitrogen flow of 2 sccm, and keeping a nitrogen pressure at 6 mTorr, the AlN nucleating layer is grown by PLD in an N-rich atmosphere. An Al source is an AlN high-purity ceramic target material.

(5) Epitaxial growth of a nonpolar Al_{0.15}Ga_{0.85}N buffer layer: By keeping parameters the same as those in Step (4), and changing a target material into gallium-rich AlGaN ceramic, the nonpolar Al_{0.15}Ga_{0.85}N buffer layer is grown on the nonpolar AlN buffer layer in-situ.

(6) Growth of a nonpolar Al_{0.7}Ga_{0.3}N epitaxial layer: By keeping parameters the same as those in Step (4), and changing the target material into aluminum-rich AlGaN ceramic, the nonpolar Al_{0.7}Ga_{0.3}N buffer layer is grown on the nonpolar Al_{0.15}Ga_{0.85}N buffer layer in-situ.

As shown in FIG. 1, the epitaxial structure of a nonpolar AlGaN-based DUV photoelectric detector prepared in the embodiment includes the nonpolar AlN buffer layer 2, the nonpolar Al_{0.15}Ga_{0.85}N buffer layer 3, and the nonpolar Al_{0.7}Ga_{0.3}N epitaxial layer 4 that are sequentially grown on the LaAlO₃ substrate 1. The nonpolar AlN buffer layer has a thickness of 300 nm. The nonpolar Al_{0.15}Ga_{0.85}N buffer layer has a thickness of 360 nm. The nonpolar Al_{0.7}Ga_{0.3}N epitaxial layer has a thickness of 500 nm.

### Embodiment 2

The embodiment provides a preparation method of an epitaxial structure of an N-polar-plane AlAlGaN-based DUV photoelectric detector, specifically including the following steps:

(1) Selection of a substrate and a crystal orientation: The LaAlO₃ substrate takes a (100) close-packed plane as an epitaxial plane, and an AlN[11-20] direction as an epitaxial growth direction of a material.

(2) Surface cleaning of the substrate: The LaAlO₃ substrate is sequentially put into acetone, anhydrous ethanol and deionized water to ultrasonically clean for 5 min, taken out, washed with the deionized water, and blow-dried with hot high-purity nitrogen.

(3) Surface annealing of the substrate for impurity removal and leveling: The cleaned LaAlO₃ substrate is put into a UHV chamber. By pumping a vacuum degree in the chamber to 2.5*10-10 torr, and heating the chamber to 700° C., the substrate is annealed for 30 min.

(4) Growth of a nonpolar AlN buffer layer: by cooling the chamber to 450° C., keeping a vacuum degree in the chamber at 2.5*10-10 torr, a laser energy at 280 mJ and a laser frequency at 25 Hz, charging a nitrogen flow of 5 sccm, and keeping a nitrogen pressure at 8 mTorr, a thin film of the AlN nucleating layer is grown by PLD in an N-rich atmosphere. An Al source is an AlN high-purity ceramic target material.

(5) Epitaxial growth of a nonpolar Al_{0.15}Ga_{0.85}N buffer layer: By keeping parameters the same as those in Step (4), and changing a target material into gallium-rich AlGaN ceramic, the nonpolar Al_{0.15}Ga_{0.85}N buffer layer is grown on the nonpolar AlN buffer layer in-situ.

(6) Growth of a nonpolar Al_{0.7}Ga_{0.3}N epitaxial layer: By keeping parameters the same as those in Step (4), and changing the target material into aluminum-rich AlGaN ceramic, the nonpolar Al_{0.7}Ga_{0.3}N buffer layer is grown on the nonpolar Al_{0.15}Ga_{0.85}N buffer layer in-situ.

As shown in FIG. 1, the epitaxial structure of a nonpolar AlGaN-based DUV photoelectric detector prepared in the embodiment includes the nonpolar AlN buffer layer 2, the nonpolar Al_{0.15}Ga_{0.85}N buffer layer 3, and the nonpolar Al_{0.7}Ga_{0.3}N epitaxial layer 4 that are sequentially grown on the LaAlO₃ substrate 1. The nonpolar AlN buffer layer has a thickness of 300 nm. The nonpolar Al_{0.15}Ga_{0.85}N buffer layer has a thickness of 360 nm. The nonpolar Al_{0.7}Ga_{0.3}N epitaxial layer has a thickness of 450 nm.

### Embodiment 3

The embodiment provides a preparation method of an epitaxial structure of an N-polar-plane AlAlGaN-based DUV photoelectric detector, specifically including the following steps:

(1) Selection of a substrate and a crystal orientation: The LaAlO₃ substrate takes a (100) close-packed plane as an epitaxial plane, and an AlN[11-20] direction as an epitaxial growth direction of a material.

(2) Surface cleaning of the substrate: The LaAlO₃ substrate is sequentially put into acetone, anhydrous ethanol and deionized water to ultrasonically clean for 5 min, taken out, washed with the deionized water, and blow-dried with hot high-purity nitrogen.

(3) Surface annealing of the substrate for impurity removal and leveling: The cleaned LaAlO₃ substrate is put into a UHV chamber. By pumping a vacuum degree in the chamber to 2.5*10-10 torr, and heating the chamber to 800° C., the substrate is annealed for 30 min.

(4) Growth of a nonpolar AlN buffer layer: by cooling the chamber to 450° C., keeping a vacuum degree in the chamber at 2.5*10-10 torr, a laser energy at 300 mJ and a laser frequency at 30 Hz, charging a nitrogen flow of 8 sccm, and keeping a nitrogen pressure at 10 mTorr, a thin film of the AlN nucleating layer is grown by PLD in an N-rich atmosphere. An Al source is an AlN high-purity ceramic target material.

(5) Epitaxial growth of a nonpolar Al_{0.15}Ga_{0.85}N buffer layer: By keeping parameters the same as those in Step (4), and changing a target material into gallium-rich AlGaN ceramic, the nonpolar Al_{0.15}Ga_{0.85}N buffer layer is grown on the nonpolar AlN buffer layer in-situ.

(6) Growth of a nonpolar Al_{0.7}Ga_{0.3}N epitaxial layer: By keeping parameters the same as those in Step (4), and changing the target material into aluminum-rich AlGaN ceramic, the nonpolar Al_{0.7}Ga_{0.3}N buffer layer is grown on the nonpolar Al_{0.15}Ga_{0.85}N buffer layer in-situ.

As shown in FIG. 1, the epitaxial structure of a nonpolar AlGaN-based DUV photoelectric detector prepared in the embodiment includes the nonpolar AlN buffer layer 2, the nonpolar Al_{0.15}Ga_{0.85}N buffer layer 3, and the nonpolar Al_{0.7}Ga_{0.3}N epitaxial layer 4 that are sequentially grown on the LaAlO₃ substrate 1. The nonpolar AlN buffer layer has a thickness of 350 nm. The nonpolar Al_{0.15}Ga_{0.85}N buffer layer has a thickness of 380 nm. The nonpolar Al_{0.7}Ga_{0.3}N epitaxial layer has a thickness of 500 nm.

In conclusion, the epitaxial structure of a nonpolar AlGaN-based DUV photoelectric detector provided by the present disclosure includes the nonpolar AlN buffer layer, the nonpolar Al_{0.15}Ga_{0.85}N buffer layer, and the nonpolar Al_{0.7}Ga_{0.3}N epitaxial layer that are sequentially grown on the LaAlO₃ substrate. The LaAlO₃ substrate takes the (100) plane as the epitaxial plane, and the AlN[11-20] as the epitaxial growth direction, so the present disclosure enhances a power and a detectivity of the AlGaN-based DUV photoelectric detector, and improves photoresponse of the DUV photoelectric detector. The epitaxial structure of a nonpolar AlGaN-based DUV photoelectric detector provided by the present disclosure reduces a dislocation density and a surface roughness of the grown nonpolar AlGaN epitaxial layer, reduces the dark current of the detector, accelerates the photoresponse and detectivity, and enhances overall performance of the nonpolar AlGaN-based DUV photoelectric detector.

The above described are merely preferred embodiments of the present disclosure, and the protection scope of the present disclosure is not limited thereto. Any equivalent substitutions or changes made by those skilled in the art according to the technical solutions and concepts of the present disclosure within the technical scope of the present disclosure should fall within the protection scope of the present disclosure.

What is claimed is:

1. An epitaxial structure of a nonpolar AlGaN-based deep-ultraviolet (DUV) photoelectric detector, comprising a LaAlO₃ substrate, wherein a nonpolar AlN buffer layer, a nonpolar Al_{0.15}Ga_{0.85}N buffer layer, and a nonpolar Al_{0.7}Ga_{0.3}N epitaxial layer are sequentially grown on the LaAlO₃ substrate; and the LaAlO₃ substrate takes a (100) plane as an epitaxial plane, and AlN[11-20] as an epitaxial growth direction.

2. The epitaxial structure of the nonpolar AlGaN-based DUV photoelectric detector according to claim 1, wherein the nonpolar AlN buffer layer has a thickness of 300 nm to 400 nm.

3. The epitaxial structure of the nonpolar AlGaN-based DUV photoelectric detector according to claim 1, wherein the nonpolar Al_{0.15}Ga_{0.85}N buffer layer has a thickness of 350 nm to 400 nm.

4. The epitaxial structure of the nonpolar AlGaN-based DUV photoelectric detector according to claim 1, wherein the nonpolar Al_{0.7}Ga_{0.3}N epitaxial layer has a thickness of 450 nm to 550 nm.

5. A preparation method of an epitaxial structure of a nonpolar AlGaN-based deep-ultraviolet (DUV) photoelectric detector, comprising: selecting a LaAlO₃ substrate, and cleaning a surface of the LaAlO₃ substrate to obtain a cleaned LaAlO₃ substrate;
putting the cleaned LaAlO₃ substrate into an ultrahigh vacuum (UHV) chamber, and annealing the cleaned LaAlO₃ substrate at a high temperature to remove surface contamination;
charging nitrogen to the UHV chamber, and epitaxially growing a nonpolar AlN buffer layer on the LaAlO₃ substrate by pulsed laser deposition (PLD);
changing a target material in an environment of growing the nonpolar AlN buffer layer, and growing a nonpolar Al_{0.15}Ga_{0.85}N buffer layer on the nonpolar AlN buffer layer in-situ; and
changing the target material in the environment of growing the nonpolar AlN buffer layer, and growing a nonpolar Al_{0.7}Ga_{0.3}N epitaxial layer on the Al_{0.15}Ga_{0.85}N buffer layer;
wherein the LaAlO₃ substrate takes a (100) plane as an epitaxial plane, and AlN[11-20] as an epitaxial growth direction.

6. The preparation method according to claim 5, wherein the environment of growing the nonpolar AlN buffer layer is as follows: by keeping a vacuum degree in the UHV chamber, a laser energy at 220 mJ to 300 mJ, a laser frequency at 15 Hz to 30 Hz, a nitrogen flow at 2 sccm to 8 sccm, and a nitrogen pressure in the UHV chamber at 6 mTorr to 10 mTorr, the nonpolar AlN buffer layer is grown in an N-rich atmosphere.

7. The preparation method according to claim 5, wherein the nonpolar AlN buffer layer is epitaxially grown on the LaAlO₃ substrate, and an Al source is an AlN high-purity ceramic target material.

8. The preparation method according to claim 5, wherein the nonpolar Al_{0.15}Ga_{0.85}N buffer layer is grown on the nonpolar AlN buffer layer in-situ, and the target material is gallium-rich AlGaN ceramic.

9. The preparation method according to claim 5, wherein the nonpolar Al_{0.7}Ga_{0.3}N epitaxial layer is grown on the Al_{0.15}Ga_{0.85}N buffer layer, and the target material is aluminum-rich AlGaN ceramic.

10. The preparation method according to claim 5, wherein the nonpolar AlN buffer layer has a thickness of 300 nm to 400 nm;
the nonpolar Al_{0.15}Ga_{0.85}N buffer layer has a thickness of 350 nm to 400 nm; and
the nonpolar Al_{0.7}Ga_{0.3}N epitaxial layer has a thickness of 450 nm to 550 nm.
